(19) United States
(12) Patent Application Publication
(10) Pub. No.: US 2011/0027725 A1
(43) Pub. Date: Feb. 3, 2011

(54) POLYOL COMPOUND FOR PHOTORESIST

(76) Inventors: Kiyoharu Tsutsumi, Hyogo (JP); Yoshinori Funaki, Hyogo (JP); Arimichi Okumura, Hyogo (JP)

Correspondence Address: BIRCH STEWART KOLASCH & BIRCH, PO BOX 747, FALLS CHURCH, VA, 22040-0747, US

(21) Appl. No.: 12/935,537

(22) PCT Filed: Apr. 2, 2009
(86) PCT No.: PCT/JP2009/001557

§ 371 Date: Sep. 29, 2010

(30) Foreign Application Priority Data
Apr. 4, 2008 (JP) 2008-098507

(51) Int. Cl. G03F 7/20; C08G 65/38; C08G 8/02

(52) U.S. Cl. 430/325; 528/219; 528/128

(57) ABSTRACT

A polyol compound for photoresists has at least one aliphatic group and at least one aromatic group bound to each other alternately, in which the aromatic group has at least one aromatic ring and two or more hydroxyl groups bound to the aromatic ring. The polyol compound for photoresists can be prepared through an acid-catalyzed reaction, such as a Friedel-Crafts reaction, between an aliphatic polyol and an aromatic polyol. The aliphatic polyol is preferably an alicyclic polyol. The aromatic polyol is preferably hydroquinone.

By protecting phenolic hydroxyl group(s) thereof with a protecting group capable of leaving with an acid, the polyol compound for photoresists gives a compound for photoresists. A photoresist composition containing this compound can form a resist pattern which shows less line edge roughness (LER), excels in resolution and etching resistance, and is fine and sharp.

### TECHNICAL FIELD

The present invention relates to a novel polyol compound for photoresists containing at least one aliphatic group and at least one aromatic group bound to each other alternately, the aromatic group having at least one aromatic ring and two or more hydroxyl groups bound to the aromatic ring. The present invention also relates to a compound for photoresists containing one or more phenolic hydroxyl groups in the polyol compound for photoresists, the phenolic hydroxyl groups being protected by protecting groups capable of leaving with an acid; a photoresist composition containing the compound for photoresists; a process for the formation of a resist pattern using the photoresist composition; and a process for the production of the polyol compound for photoresists.

### BACKGROUND ART

Recent improvements in lithographic technologies rapidly move patterning for the production of semiconductor devices and liquid crystal displays to finer design rules.

Such patterning in finer design rules has been generally achieved by adopting light sources having shorter wavelengths. Specifically, ultraviolet rays represented by g line (g ray) and i line (i ray) were customarily used, but commercial production of semiconductor devices using KrF excimer laser and ArF excimer laser has been launched. Further recently, lithography processes using extreme ultraviolet (EUV; at a wavelength of about 13.5 nm) and those using electron beams have been proposed as next-generation technologies succeeding to the lithography processes using ArF excimer laser (193 nm).

Chemically-amplified resists are known as one of resist materials which have such high resolutions as to reproduce patterns with fine dimensions. The chemically-amplified resists each contain a base component capable of forming a film and capable of becoming soluble in an alkali by the action of an acid; and an acid generator component capable of generating an acid upon irradiation with light (upon exposure).

Such resist materials, when used for the formation of a pattern, cause roughness of the top surface and sidewall surface of the pattern. The roughness was trivial in the past but has recently become a serious problem, because further higher resolutions, such as resolutions to give a dimensional width of about 22 nm, are demanded in production typically of semiconductor devices in finer design rules. For example, when a line pattern is formed, the roughness of the sidewall surface of the pattern, i.e., line edge roughness (LER) causes a variation in line width. The variation in line width is desirably controlled to be about 10% or less of the ideal width, but LER more affects the variation in line width with decreasing pattern dimensions. However, customarily used polymers are difficult to give resist patterns with less LER, because they have a large average particle diameter of about several nanometers per one molecule.

An exemplary candidate for the reduction of LER by adopting a polymer having a small average particle diameter per one molecule is a resist composition described in Patent Document 1. This resist composition contains a polyhydric phenol compound and an acid generator component capable of generating an acid upon exposure. The resist composition is, however, not always satisfactory in resolution and etching resistance. Specifically, under present circumstances, there has been found no resist composition which can give a resist pattern with less LER while exhibiting excellent resolution and high etching resistance.

### Citation List

### Patent Document

Patent Document 1: Japanese Unexamined Patent Application Publication (JP-A) No. 2006-78744

### SUMMARY OF INVENTION

### Technical Problem

Accordingly, an object of the present invention is to provide a novel polyol compound for photoresists that can give a resist pattern with less LER and excels in resolution and etching resistance.

Another object of the present invention is to provide a compound for photoresists containing one or more hydroxyl groups of the polyol compound for photoresists, the hydroxyl groups are protected by protecting groups capable of leaving with an acid. (i.e., compound for photoresists, corresponding to the polyol compound for photoresists, except for hydroxyl group(s) of the polyol compound being protected by protecting groups capable of leaving with an acid); a photoresist composition containing the compound for photoresists; a process for the formation of a resist pattern using the photoresist composition; and a process for efficiently producing the polyol compound for photoresists.

### Means for Solving the Problems

After intensive investigations to solve the problems, the present inventors have found a novel polyol compound containing at least one aliphatic group and at least one aromatic group bound to each other alternately, the aromatic group having at least one aromatic ring and two or more hydroxyl groups bound to the aromatic ring, and they have found that, by protecting part or all of phenolic hydroxyl groups of the polyol compound with protecting groups capable of leaving with an acid, the resulting protected compound, when used as a base material for photoresists composition, gives a resist pattern which shows less LER and achieves excellent resolution and high etching resistance. The present invention has been made based on these findings and further investigations.

Specifically, the present invention provides, in an embodiment, a polyol compound for photoresists, containing at least one aliphatic group and at least one aromatic group bound to each other alternately, the aromatic group having at least one aromatic ring and two or more hydroxyl groups bound to the aromatic ring.

The polyol compound for photoresists is preferably prepared through an acid-catalyzed reaction between an aliphatic polyol and an aromatic polyol, and is more preferably prepared through a Friedel-Crafts reaction between them.

The aliphatic polyol is preferably an alicyclic polyol, of which an adamantanepolyol containing an adamantane ring and two or more hydroxyl groups bound at the tertiary positions of the adamantane ring is more preferred.

The aromatic polyol is preferably hydroquinone or a naphthalenepolyol.

The polyol compound for photoresists preferably has a weight-average molecular weight of 500 to 5000.

The present invention provides, in another embodiment, a compound for photoresists, comprising one or more phenolic hydroxyl groups of the polyol compound for photoresists, the phenolic hydroxyl groups being protected by protecting groups capable of leaving with an acid in part or all of the phenolic hydroxyl groups.

Preferably, an acetal structure is formed as a result of the protection of the phenolic hydroxyl group of the polyol compound for photoresists by the protecting group capable of leaving with an acid. The acetal structure is preferably formed through a reaction of the phenolic hydroxyl group with a vinyl ether compound.

The present invention further provides, in still another embodiment, a photoresist composition containing at least the compound for photoresists.

In yet another embodiment, the present invention provides a process for the formation of a resist pattern. The process includes the steps of forming a resist film from the photoresist composition; pattern-wise exposing the resist film; and developing the pattern-wise-exposed resist film.

The present invention provides, in another embodiment, a process for the production of a polyol compound for photoresists. The process includes the step of carrying out an acid-catalyzed reaction between an aliphatic polyol and an aromatic polyol to give a polyol compound containing at least one aliphatic group and at least one aromatic group bound to each other alternately, the aromatic group having at least one aromatic ring and two or more hydroxyl groups bound to the aromatic ring.

The production process may further include the step of mixing a solution of the polyol compound for photoresists with a poor solvent with respect to a compound having one or more phenolic hydroxyl groups to deposit or separate as a different layer hydrophobic impurities to thereby remove the hydrophobic impurities, the polyol compound having been formed through the acid-catalyzed reaction between the aliphatic polyol and the aromatic polyol and containing at least one aliphatic group and at least one aromatic group bound to each other alternately, the aromatic group having at least one aromatic ring and two or more hydroxyl groups bound to the aromatic ring.

The production process may further include the step of mixing the solution, from which the hydrophobic impurities have been removed, with a poor solvent with respect to a compound having one or more phenolic hydroxyl groups to thereby deposit or separate as a different layer the polyol compound for photoresists, in which the polyol compound contains at least one aliphatic group and at least one aromatic group bound to each other alternately, and the aromatic group has an aromatic ring and two or more hydroxyl groups on the aromatic ring.

The poor solvent for use in the deposition or layer-separation of the hydrophobic impurities can be one selected from the group consisting of a solvent mixture containing water and a water-miscible organic solvent; water; and a hydrocarbon.

### Advantages

The polyol compound for photoresists according to the present invention is a polyol compound for photoresists which contains at least one aliphatic group and at least one aromatic group bound to each other alternately, in which the aromatic group has an aromatic ring and two or more hydroxyl groups on the aromatic ring. The polyol compound gives a compound for photoresists by protecting phenolic hydroxyl groups of the polyol compound with protecting groups capable of leaving with an acid. The compound for photoresists, when used in a photoresist composition, can give a resist pattern which shows less LER, excels in resolution and high etching resistance, and is fine and sharp.

### DESCRIPTION OF EMBODIMENTS

[Polyol Compounds for Photoresists]

Polyol compounds for photoresists according to the present invention each contain at least one aliphatic group and at least one aromatic group bound to each other alternately, the aromatic group having at least one aromatic ring and two or more hydroxyl groups bound to the aromatic ring.

The polyol compounds for photoresists according to the present invention have a structure in which at least one aliphatic group and at least one aromatic group are bound to each other alternately, and the aromatic group has an aromatic ring and two or more hydroxyl groups on the aromatic ring. Examples of the polyol compounds having such structure include polyol compounds for photoresists each having one unit (repeating unit) composed of one aliphatic group and one aromatic group bound to each other, such as a compound having one aliphatic group and one or more aromatic groups bound thereto, and a compound having one aromatic group and two or more aliphatic groups bound thereto; polyol compounds for photoresists each having two or more of the repeating unit; and mixtures of these.

The polyol compounds for photoresists can be produced according to a variety of processes, such as a process of subjecting an aliphatic polyol and an aromatic polyol to an acid-catalyzed reaction; a process of subjecting an aliphatic multivalent halide and an aromatic polyol to an acid-catalyzed reaction; and a process of subjecting phenol and formaldehyde to an acid-catalyzed reaction or alkali-catalyzed reaction. Among them, the process of subjecting an aliphatic polyol and an aromatic polyol to an acid-catalyzed reaction is preferably adopted in the present invention to produce the polyol compounds.

The acid-catalyzed reaction between an aliphatic polyol and an aromatic polyol in the present invention is preferably a Friedel-Crafts reaction.

(Aliphatic Polyols)

The aliphatic polyol for use in the present invention is a compound having an aliphatic hydrocarbon group and two or more hydroxyl groups bound to the aliphatic hydrocarbon group and is represented by following Formula (1):

R—(OH)ₙ₁ (1)

wherein R represents an aliphatic hydrocarbon group; and n1 denotes an integer of 2 or more.

In Formula (1), examples of R include chain aliphatic hydrocarbon groups, cyclic aliphatic (cycloaliphatic) hydrocarbon groups, and groups each containing two or more of these bound to each other. Exemplary chain aliphatic hydrocarbon groups include alkyl groups having about 1 to 20 carbon atoms, such as methyl, ethyl, propyl, isopropyl, butyl, isobutyl, s-butyl, t-butyl, pentyl, hexyl, decyl, and dodecyl groups, of which those having about 1 to 10 carbon atoms are preferred, and those having about 1 to 3 carbon atoms are more preferred; alkenyl groups having about 2 to 20 carbon atoms, such as vinyl, allyl, and 1-butenyl groups, of which those having about 2 to 10 carbon atoms are preferred, and those having about 2 or 3 carbon atoms are more preferred; and alkynyl groups having about 2 to 20 carbon atoms, such as ethynyl and propynyl groups, of which those having about 2 to 10 carbon atoms are preferred, and those having about 2 or 3 carbon atoms are more preferred.

Exemplary cycloaliphatic hydrocarbon groups include cycloalkyl groups having about 3 to 20 members, such as cyclopropyl, cyclobutyl, cyclopentyl, cyclohexyl, and cyclooctyl groups, of which those having about 3 to 15 members are preferred, and those having about 5 to 8 members are more preferred; cycloalkenyl groups having about 3 to 20 members, such as cyclopentenyl and cyclohexenyl groups, of which those having about 3 to 15 members are preferred, and those having about 5 to 8 members are more preferred; and bridged hydrocarbon groups such as perhydronaphth-1-yl group, norbornyl, adamantyl, and tetracyclo[4.4.0.1^{2.5}1^{7.10}] dodec-3-yl groups.

Exemplary hydrocarbon groups each containing a chain aliphatic hydrocarbon group and a cycloaliphatic hydrocarbon group bound to each other include cycloalkyl-alkyl groups such as cyclopentylmethyl, cyclohexylmethyl, and 2-cyclohexylethyl groups, of which cycloalkyl-alkyl groups whose cycloalkyl moiety having 3 to 20 carbon atoms and whose alkyl moiety having 1 to 4 carbon atoms are preferred.

The hydrocarbon groups may each have one or more substituents such as halogen atoms, oxo group, hydroxyl group, substituted oxy groups (e.g., alkoxy groups, aryloxy groups, aralkyloxy groups, and acyloxy groups), carboxyl group, substituted oxycarbonyl groups (e.g., alkoxycarbonyl groups, aryloxycarbonyl groups, and aralkyloxycarbonyl groups), substituted or unsubstituted carbamoyl groups, cyano group, nitro group, substituted or unsubstituted amino groups, sulfo group, and heterocyclic groups. The hydroxyl group and carboxyl group may be respectively protected by protecting groups customarily used in organic syntheses.

The aliphatic polyol for use in the present invention is preferably an alicyclic polyol for further higher etching resistance. The alicyclic polyol is a compound having an alicyclic skeleton, and the hydroxyl groups may be bound to the alicyclic skeleton directly or indirectly through linkage groups. Exemplary linkage groups include alkylene groups (e.g., alkylene groups having 1 to 6 carbon atoms); and groups each including one or more of the alkylene groups and at least one group selected from the group consisting of —O—, —C(═O)—, —NH—, and —S— bound to each other.

Examples of the alicyclic polyol include alicyclic polyols such as cyclohexanediol, cyclohexanetriol, cyclohexanedimethanol, isopropylidenedicyclohexanol, decahydronaphthalenediol (decalindiol), and tricyclodecanedimethanol; and bridged alicyclic polyols of Formula (1), wherein R is a ring selected from rings represented by following Formulae (2a) to (2j) or a ring including two or more of these rings bound to each other, and wherein two or more hydroxyl groups are bound to R.

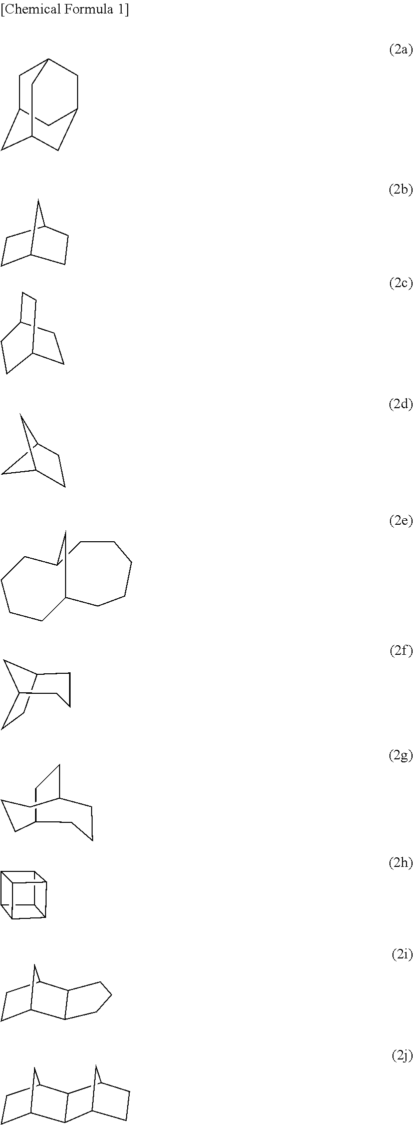

Of such aliphatic polyols for use in the present invention, bridged alicyclic polyols are preferred, of which adamantanepolyols each having an adamantane ring (2a) and two or more hydroxyl groups bound at the tertiary positions of the adamantane ring are more preferred for further higher etching resistance.

(Aromatic Polyols)

The aromatic polyol for use in the present invention is a compound having at least one aromatic ring and two or more hydroxyl groups bound to the aromatic ring and is represented by following Formula (3):

R′—(OH)ₙ₂ (3)

wherein R′ represents an aromatic hydrocarbon group; and n2 denotes an integer of 2 or more. When R′ has two or more aromatic rings, the two or more hydroxyl groups may be bound to the same aromatic ring or to different aromatic rings.

Examples of R′ in Formula (3) include aromatic hydrocarbon groups; and groups each containing an aromatic hydrocarbon group to which a chain aliphatic hydrocarbon group and/or cycloaliphatic hydrocarbon group is bound. Exemplary aromatic hydrocarbon groups include aromatic hydrocarbon groups having about 6 to 14 carbon atoms, such as phenyl and naphthyl groups, of which those having about 6 to 10 carbon atoms are preferred. Examples of the chain aliphatic hydrocarbon group and of the cycloaliphatic hydrocarbon group are as with the examples of the chain aliphatic hydrocarbon groups and cycloaliphatic hydrocarbon groups as R.

Exemplary groups each having an aromatic hydrocarbon group to which a chain aliphatic hydrocarbon group is bound include alkyl-substituted aryl groups, such as phenyl group or naphthyl group on which about one to four alkyl groups having 1 to 4 carbon atoms are substituted.

The aromatic hydrocarbon group may have one or more substituents such as halogen atoms, oxo group, hydroxyl group, substituted oxy groups (e.g., alkoxy groups, aryloxy groups, aralkyloxy groups, and acyloxy groups), carboxyl group, substituted oxycarbonyl groups (e.g., alkoxycarbonyl groups, aryloxycarbonyl group, and aralkyloxycarbonyl groups), substituted or unsubstituted carbamoyl groups, cyano group, nitro group, substituted or unsubstituted amino groups, sulfo group, and heterocyclic groups. The hydroxyl group and carboxyl group may be respectively protected by protecting groups customarily used in organic syntheses. An aromatic or nonaromatic heterocyclic ring may be fused (condensed) to the ring of the aromatic hydrocarbon group.

Exemplary aromatic polyols for use in the present invention include hydroquinone; resorcinol; naphthalenepolyols such as 1,3-dihydroxynaphthalene and 1,4-dihydroxynaphthalene; biphenols; bis(4-hydroxyphenyl)methane; bisphenol-A; and 1,1,1-(4-hydroxyphenyl)ethane. Among them, hydroquinone and naphthalenepolyols are easily available and are advantageously used in the present invention.

Exemplary acid catalysts for sue in the acid-catalyzed reaction include Lewis acids such as aluminum chloride, iron(III) chloride, tin(IV) chloride, and zinc(II) chloride; and protonic acids such as HF (hydrogen fluoride), sulfuric acid, p-toluenesulfonic acid, and phosphoric acid. Each of these can be used alone or in combination. Typically in the production of semiconductor devices, organic acids such as sulfuric acid and p-toluenesulfonic acid are preferably used as the acid catalysts, because the production should be performed while avoiding contamination of metal components. Such acid catalysts are used in an amount of, for example, about 0.01 to 10 moles and preferably about 0.1 to 5 moles, per 1 mole of the aliphatic polyol.

The acid-catalyzed reaction is performed in the presence of, or in the absence of, a solvent inert to the reaction. Examples of the solvent include hydrocarbons such as hexane, cyclohexane, and toluene; halogenated hydrocarbons such as methylene chloride, 1,2-dichloroethane, chloroform, carbon tetrachloride, and chlorobenzene; chain or cyclic ethers such as diethyl ether, dimethoxyethane, tetrahydrofuran, and dioxane; nitriles such as acetonitrile and benzonitrile; esters such as ethyl acetate and n-butyl acetate; carboxylic acids such as acetic acid; amides such as N,N-dimethylformamide; ketones such as acetone and methyl ethyl ketone; nitro compounds such as nitromethane and nitrobenzene; and mixtures of them.

The reaction temperature in the acid-catalyzed reaction can be chosen as appropriate according typically to the types of reaction components. Typically, when 1,3,5-adamantanetriol and hydroquinone are used as the aliphatic polyol and the aromatic polyol, respectively, the reaction is performed at a temperature of typically around room temperature (25° C.) to 200° C. and preferably around 50° C. to 150° C. The reaction can be performed according to any system such as batch system, semi-batch system, or continuous system.

The aromatic polyol is used in an amount of generally about 1.0 to 100 moles, preferably about 3.0 to 50 moles, and more preferably about 5.0 to 20 moles, per 1 mole of the aliphatic polyol. The aromatic polyol may be used in large excess.

The reaction gives a corresponding polyol compound for photoresists. After the completion of the reaction, the reaction product can be separated and purified by a common separation/purification procedure such as adjustment of acidity or alkalinity, filtration, concentration, crystallization, washing, recrystallization, and/or column chromatography. A solvent for crystallization (crystallization solvent) can be any solvent in which the produced polyol compound for photoresists is insoluble, and examples thereof include hydrocarbons such as hexane, heptane, and cyclohexane. In a preferred embodiment of the present invention, a solvent mixture is used as the crystallization solvent, which solvent mixture contains both a solvent in which the produced polyol compound for photoresists is insoluble and another solvent in which the material aliphatic polyol and aromatic polyol are soluble. This is because the use of the solvent mixture helps to remove the residual material aliphatic polyol and aromatic polyol more easily, resulting in higher purification efficiency. Examples of the solvent in which the material aliphatic polyol and aromatic polyol are soluble include ethers such as tetrahydrofuran; ketones such as acetone and 2-butanone; esters such as ethyl acetate; and alcohols such as methanol and ethanol. The mixing ratio of respective solvents in the solvent mixture can be adjusted as appropriate. As used herein the term “crystallization” (deposition) also means and includes precipitation or settlement.

The reaction product often contains components insoluble in an alkaline developer. Examples of such components include (i) components having relatively high molecular weights of more than 2000; and (ii) compounds, even having molecular weights of 1000 to 2000, containing phenolic hydroxyl groups of the polyol compound for photoresists which have been sealed or blocked typically through transesterification with the solvent during the reaction. If a polyol compound containing components insoluble in an alkaline developer is used for resist, the insoluble components may adversely affect the roughness in patterning and/or may cause particles during development, and the particles may remain as foreign substances in the formed pattern. To avoid these, it is preferred to provide the step of mixing a solution of the polyol compound for photoresists in a solvent with a poor solvent with respect to a compound having one or more phenolic hydroxyl groups to deposit or separate as a different layer (to separate as a liquid) hydrophobic impurities to thereby remove the hydrophobic impurities. This step, when provided, helps to remove the components efficiently and to produce a high-purity polyol compound for photoresists efficiently, and the resulting polyol compound is useful for the preparation of a resist composition which gives a resist pattern with less LER while exhibiting excellent resolution and high etching resistance.

Examples of the solvent for preparing the solution of the polyol compound for photoresists include ethers such as tetrahydrofuran; ketones such as acetone and 2-butanone; esters such as ethyl acetate and n-butyl acetate; and alcohols such as methanol and ethanol. Each of these solvents can be used alone or in combination. The solution of the polyol compound for photoresists to be subjected to removal operation of hydrophobic impurities can be either a reaction solution (reaction mixture) obtained as a result of the acid-catalyzed reaction, or a solution obtained by subjecting the reaction solution to an operation such as dilution, concentration, filtration, adjustment of acidity or alkalinity, and/or solvent exchange.

The solution of the polyol compound for photoresists to be subjected to the removal operation of hydrophobic impurities has a content of the polyol compound for photoresists of typically 1 to 40 percent by weight and preferably 3 to 30 percent by weight.

Examples of the poor solvent with respect to a compound having one or more phenolic hydroxyl groups include solvents having a solubility of phenol (25° C.) of 1 g/100 g or less. Specific examples of the poor solvent with respect to a compound having one or more phenolic hydroxyl groups include hydrocarbons including aliphatic hydrocarbons such as hexane and heptane, and alicyclic hydrocarbons such as cyclohexane; solvent mixtures each containing water and one or more water-miscible organic solvents (e.g., alcohols such as methanol and ethanol; ketones such as acetone; nitriles such as acetonitrile; and cyclic ethers such as tetrahydrofuran); and water. Each of these solvents can be used alone or in combination. The amount of the poor solvent is, for example, 1 to 55 parts by weight and preferably 5 to 50 parts by weight, per 100 parts by weight of the solution containing the polyol compound for photoresists.

Upon mixing of the solution of the polyol compound for photoresists and the poor solvent, it is acceptable to add the poor solvent to the solution of the polyol compound for photoresists or to add the solution of the polyol compound for photoresists to the poor solvent; but it is more preferred to add the poor solvent to the solution of the polyol compound for photoresists.

The hydrophobic impurities precipitated or separated as a different layer can be removed according to a procedure such as filtration, centrifugal separation, or decantation. The solution after the removal of the hydrophobic impurities is further mixed with another portion of the poor solvent with respect to a compound having one or more phenolic hydroxyl groups to thereby allow the polyol compound for photoresists to deposit or to be separated as a different layer. In this procedure, it is acceptable to add the poor solvent to the solution after removal of the hydrophobic impurities or to add the solution after removal of the hydrophobic impurities to the poor solvent; but it is more preferred to add the solution after removal of the hydrophobic impurities to the poor solvent. The amount of the poor solvent in this step is typically 60 to 1000 parts by weight and preferably 65 to 800 parts by weight, per 100 parts by weight of the solution after removal of the hydrophobic impurities (the solution containing the polyol compound for photoresists).

The deposited or layer-separated polyol compound for photoresists can be recovered typically through filtration, centrifugal separation, or decantation. The poor solvent for use in the deposition or layer-separation of the hydrophobic impurities may be the same as or different from the poor solvent for use in the deposition or layer-separation of the target polyol compound for photoresists. Where necessary, the obtained polyol compound for photoresists is subjected to drying.

The polyol compounds for photoresists according to the present invention have weight-average molecular weights (Mw) of about 500 to 5000, preferably about 1000 to 3000, and more preferably about 1000 to 2000. A polyol compound for photoresists, if having a weight-average molecular weight of more than 5000, may have excessively large particle diameters and may tend to not sufficiently help to reduce LER. In contrast, a polyol compound for photoresists, if having a weight-average molecular weight of less than 500, may tend to show insufficient thermal stability. The polyol compounds have molecular weight distributions (Mw/Mn) of typically about 1.0 to 2.5. The symbol Mn represents a number-average molecular weight, and both Mn and Mw are values in terms of standard polystyrene.

Examples of the polyol compounds for photoresists according to the present inventions include compounds represented by following Formulae (4a), (4b), and (4c), in which “s”, “t”, and “u” may be the same as or different from one another and each represent an integer of 0 or more; and the symbol “. . . . ” indicates that a repeating unit of “adamantane ring-hydroquinone” may be further repeated or terminated here.

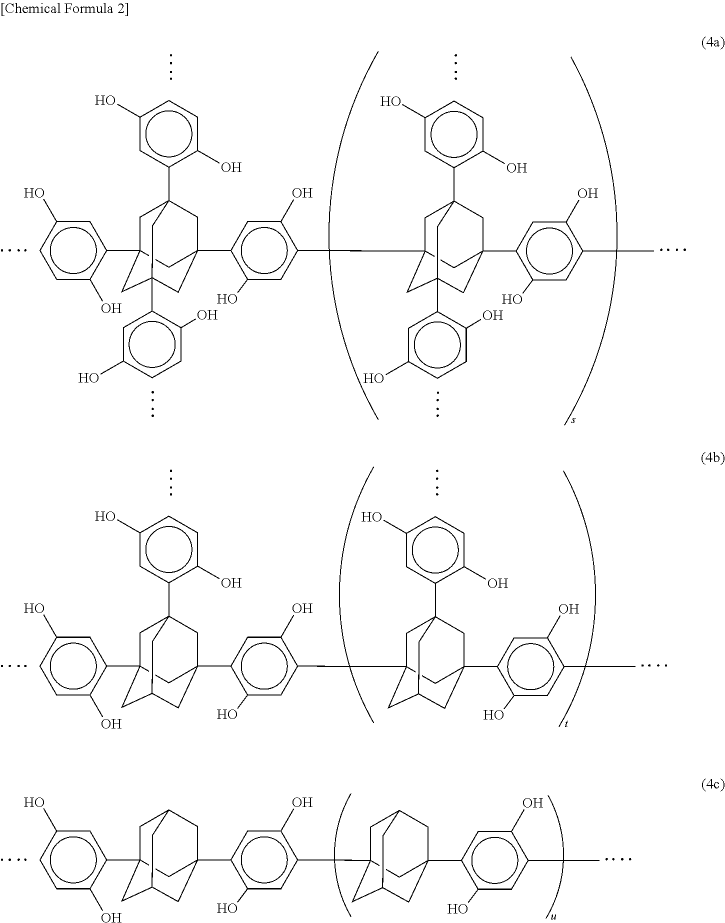

[Compounds for Photoresists]

Compounds for photoresists according to the present invention contain one or more phenolic hydroxyl groups in any of the polyol compounds for photoresists, in which the phenolic hydroxyl groups are protected by protecting groups capable of leaving with an acid (i.e., compounds for photoresists each correspond to any of the polyol compounds for photoresists, except for part or all of phenolic hydroxyl groups thereof being protected by protecting groups capable of leaving with an acid.) The polyol compound for photoresists according to the present invention having phenolic hydroxyl groups is soluble in an alkaline developer and, by protecting the phenolic hydroxyl group(s) thereof with a protecting group capable of leaving with an acid, is advantageously usable as a base material for a positive-working photoresist composition.

Exemplary structures formed by the protection of the phenolic hydroxyl group(s) of the polyol compound for photoresists by the protecting group capable of leaving with an acid include tertiary ester, formal, acetal, ketal, and carbonate structures. Among them, an acetal structure is preferred in the present invention as the structure formed by the protection of the phenolic hydroxyl group of the polyol compound for photoresists by the protecting group capable of leaving with an acid, because the resulting compound having such acetal structure shows a higher sensitivity.

The acetal structure can be formed according to a variety of techniques without limitation, such as a technique of reacting a phenolic hydroxyl group of the polyol compound for photoresists with a 1-halogenated ethyl ether compound; or a technique of reacting a phenolic hydroxyl group of the polyol compound for photoresists with a vinyl ether compound. The technique of reacting a phenolic hydroxyl group of the polyol compound for photoresists with a vinyl ether compound is preferably adopted in the present invention, because there are a wide variety of vinyl ether compounds usable in the technique.

The vinyl ether compound is used to form a protecting group for preventing the dissolution of the compound in an alkaline developer. For this purpose, nonpolar alkyl vinyl ether compounds and nonpolar aromatic vinyl ether compounds are preferably used.

When all the phenolic hydroxyl groups of the polyol compound for photoresists are protected by nonpolar vinyl ether compounds, the entire compound for photoresists may become hydrophobic and may tend to show insufficient adhesion to a base (substrate) and/or to show insufficient wettability with respect to an alkaline developer. To avoid these, it is desirable to control the ratio of protected phenolic hydroxyl groups to a predetermined level or to use a vinyl ether compound having a polar functional group. Examples of the polar functional groups include, but are not limited to, ether bond, ketone bond, and ester bond.

The vinyl ether compound preferably contains an electron-withdrawing group. Exemplary electron-withdrawing groups include carbonyl group, trifluoromethyl group, and cyano group. The compound for photoresists, when having an electron-withdrawing group, can have appropriately controlled capability of the protecting group for leaving with an acid and can thereby have improved storage stability.

When the resulting photoresist composition is adopted to EUV exposure, the vinyl ether compound preferably has a molecular weight equal to or higher than a predetermined value, because contamination of apparatuses due to outgassing should be avoided in such EUV exposure, and such a vinyl ether compound having a molecular weight equal to or higher than a predetermined value less causes outgassing. Specifically, the vinyl ether compound in this use preferably has a molecular weight of about 100 to 500. A vinyl ether compound, if having an excessively small molecular weight, may tend to increase the risk of contamination of the optical system due to outgassing occurring as a result of EUV exposure. In contrast, a vinyl ether compound, if having an excessively large molecular weight, may have an excessively high viscosity and may tend to become difficult to be applied to a base or substrate; and the vinyl ether compound may remain as a residue on the base or substrate after development to cause post-develop defects. The vinyl ether compound can be synthetically prepared, for example, by reacting vinyl acetate with an alcohol in the presence of an iridium catalyst.

Exemplary vinyl ether compounds for use in the present invention include monovinyl ether compounds represented by following Formulae (5a) to (5m):

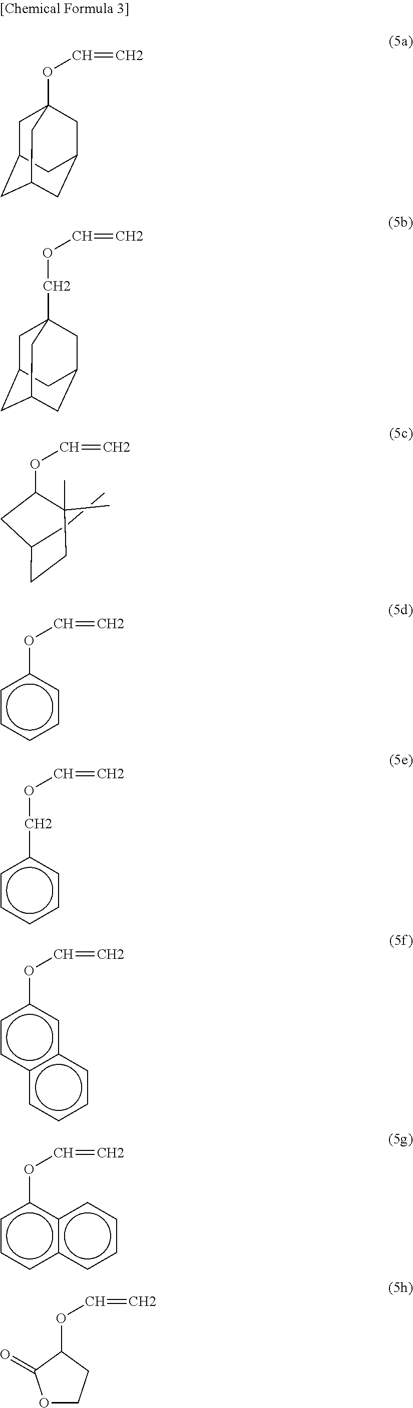

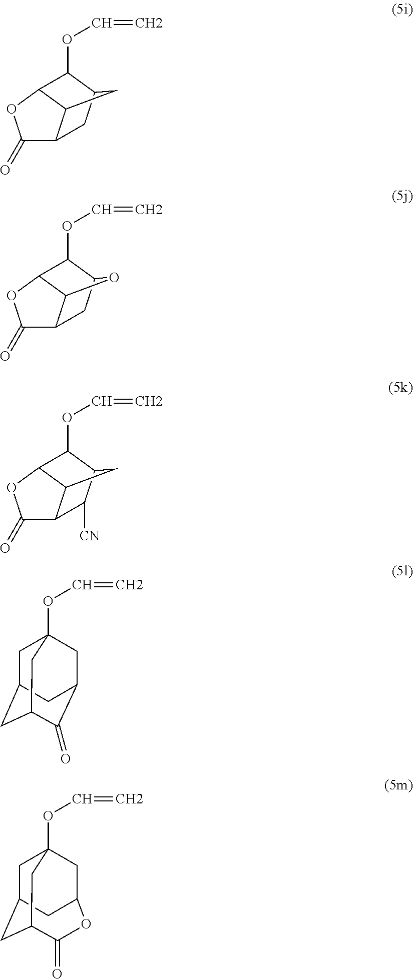

The polyol compounds for photoresists according to the present invention each have a multiplicity of phenolic hydroxyl groups. Accordingly, protection of phenolic hydroxyl group(s) of the polyol compounds for photoresists with a protecting group capable of leaving with an acid gives compounds for photoresists, and the compounds for photoresists excel in resolution and etching resistance when used in photoresist compositions. In addition, the compounds for photoresists help to reduce LER of the resist patterns and can be used as highly functional polymers in various fields.

[Photoresist Compositions]

Photoresist compositions according to the present invention each contain at least any of the compounds for photoresists. The compounds for photoresists contain one or more phenolic hydroxyl groups in any of the polyol compounds for photoresists, in which the phenolic hydroxyl groups are protected by protecting groups capable of leaving with an acid. The photoresist compositions each preferably further contain other components such as a light-activatable acid generator and a resist solvent.

Exemplary light-activatable acid generators usable herein include common or known compounds that efficiently generate an acid upon exposure, including diazonium salts, iodonium salts (e.g., diphenyliodo hexafluorophosphate), sulfonium salts (e.g., triphenylsulfonium hexafluoroantimonate, triphenylsulfonium hexafluorophosphate, triphenylsulfonium methanesulfonate, and triphenylsulfonium trifluoromethanesulfonate), sulfonic acid esters [e.g., 1-phenyl-1-(4-methylphenyl) sulfonyloxy-1-benzoylmethane, 1,2,3-trisulfonyloxymethylbenzene, 1,3-dinitro-2-(4-phenylsulfonyloxymethyl) benzene, and 1-phenyl-1-(4-methylphenylsulfonyloxymethyl)-1-hydroxy-1-benzoylmethane], oxathiazole derivatives, s-triazine derivatives, disulfone derivatives (e.g., diphenyldisulfone), imide compounds, oxime sulfonates, diazonaphthoquinone, and benzoin tosylate. Each of these light-activatable acid generators can be used alone or in combination.

The amount of the light-activatable acid generators can be chosen as appropriate according typically to the strength of the acid generated upon exposure and the proportion of the compound for photoresists, within ranges of typically about 0.1 to 30 parts by weight, preferably about 1 to 25 parts by weight, and more preferably about 2 to 20 parts by weight, per 100 parts by weight of the compound for photoresists.

Examples of the resist solvent include glycol solvents, ester solvents, ketone solvents, and solvent mixtures of them. Among these solvents, preferred are propylene glycol monomethyl ether, propylene glycol monomethyl ether acetate, ethyl lactate, methyl isobutyl ketone, methyl amyl ketone, and mixtures of them; of which more preferred are solvents each containing at least propylene glycol monomethyl ether acetate. Examples thereof include a single solvent of propylene glycol monomethyl ether acetate alone; a solvent mixture containing both propylene glycol monomethyl ether acetate and propylene glycol monomethyl ether; and a solvent mixture containing both propylene glycol monomethyl ether acetate and ethyl lactate.

The concentration of the compound for photoresists in the photoresist compositions can be set as appropriate according to the thickness of a coated film (resist film), as long as being a concentration within such a range that the photoresist composition can be applied to a substrate or base, and is, for example, about 2 to 20 percent by weight and preferably about 5 to 15 percent by weight. The photoresist compositions may further contain other components including alkali-soluble components such as alkali-soluble resins (e.g., novolak resins, phenol resins, imide resins, and carboxyl group-containing resins); and colorants (e.g., dyestuffs). The photoresist compositions may further contain any of the polyol compounds for photoresists according to the present invention, which is not protected by a group capable of leaving with an acid.

[Process for Formation of Resist Pattern]

A process for the formation of a resist pattern according to the present invention includes the steps of forming a resist film from the photoresist composition according to the present invention; pattern-wise exposing the resist film; and developing the pattern-wise-exposed resist film.

The photoresist composition is applied to a base or substrate to give a film, and the film is dried to give the resist film. The resist film is then irradiated with light (exposed to light) through a predetermined mask to form a latent-image pattern and is then developed to form a fine pattern with a high accuracy.

Exemplary materials for the base or substrate include silicon wafers, metals, plastics, glass, and ceramics. The application of the photoresist composition can be performed using a customary coating device such as spin coater, dip coater, or roller coater. The resist film has a thickness of typically about 0.01 to 10 pm and preferably about 0.03 to 1 μm.

For the exposure, light rays of different wavelengths, such as ultraviolet rays and X-rays, can be used. Typically, g line, i line, excimer laser (e.g., XeCl, KrF, KrCl, ArF, or ArCl laser), and EUV (extreme ultraviolet) are generally used for semiconductor resist use. The exposure is performed at an exposure energy of typically about 1 to 1000 mJ/cm² and preferably about 10 to 500 mJ/cm².

The exposure causes the light-activatable acid generator to generate an acid. Next, a post-exposure baking (hereinafter also referred to as “PEB treatment”) is performed to allow the generated acid to act on the protecting groups of the compound for photoresist to leave rapidly from the compound to give phenolic hydroxyl groups which help the compound to be soluble in an alkaline developer. The development with the alkaline developer gives a predetermined pattern with a high accuracy. The PEB treatment may be performed typically under conditions at a temperature of about 50° C. to 180° C. for a duration of about 0.1 to 10 minutes and preferably about 1 to 3 minutes.

The post-exposure-baked resist film is subjected to development with a developer to remove exposed portions. Thus, the resist film is patterned. The development is performed according to a procedure such as dispensing development (puddle development), dipping development, and vibration/dipping development. An alkaline aqueous solution (e.g., a 0.1 to 10 percent by weight aqueous tetramethylammonium hydroxide solution) can be used as the developer.

### EXAMPLES

The present invention will be illustrated in further detail with reference to several working examples below. It should be noted, however, that these examples are never construed to limit the scope of the present invention.

Under the following conditions, ¹H-NMR analyses and GPC measurements were performed.

Conditions for ¹H-NMR Analyses

Main unit: 500-MHz NMR analyzer supplied by JEOL Ltd.
Sample concentration: 3% (wt/wt)
Solvent: Deuterated dimethyl sulfoxide (deuterated DMSO)
Internal standard: Tetramethylsilane (TMS)

Conditions for GPC (Gel Permeation Chromatography) Measurements

Column: Three TSKgel SuperHZM-M columns
Column temperature: 40° C.

### Eluent: Tetrahydrofuran

Flow rate of eluent: 0.6 mL/min.
Sample concentration: 20 mg/mL
Injection volume: 10 μL

### Example 1

In a 200-mL three-necked flask equipped with a Dimroth condenser, a thermometer, and a stirring bar were placed 2.18 g of 1,3,5-adamantanetriol, 7.82 g of hydroquinone, 13.51 g of p-toluenesulfonic acid, and 56.67 g of n-butyl acetate, followed by stirring thoroughly. Next, the flask was purged with nitrogen and submerged in an oil bath heated to 140° C., to start heating with stirring. After being kept heating under reflux for 2 hours, the flask was cooled.

The cooled reaction solution was transferred from the flask to a separatory funnel, washed with 80 g of distilled water, and further washed with five portions of 65 g of distilled water. The washed reaction solution had a weight of 55.4 g. The washed reaction solution was poured into 500 g of n-heptane, to deposit orange fine particles. The fine particles were collected through filtration, dried at 60° C. for 12 hours, and thereby yielded 5.8 g of a polyol compound 1 for photoresists. The obtained polyol compound 1 for photoresists was subjected to a GPC measurement and found to have a weight-average molecular weight in terms of standard polystyrene of 1100 and a molecular weight distribution of 1.69. Independently, the polyol compound 1 for photoresists was subjected to a ¹H-NMR measurement in dimethyl sulfoxide-d6 and found to show peaks from protons of phenolic hydroxyl groups at around 8 to 9 ppm, peaks from aromatic protons at around 6 to 7 ppm, and peaks from protons of adamantane ring at around 1 to 3 ppm.

### Example 2

In a 200-mL three-necked flask equipped with a Dimroth condenser, a thermometer, and a stirring bar were placed 0.739 g of 1,3,5-adamantanetriol, 3.98 g of hydroquinone, 18.01 g of p-toluenesulfonic acid, and 18.01 g of n-butyl acetate, followed by stirring thoroughly. Next, the flask was purged with nitrogen and submerged in an oil bath heated to 140° C., to start heating with stirring. After being kept heating under reflux for 2 hours, the flask was cooled.

The cooled reaction solution was transferred from the flask to a separatory funnel and washed with six portions of 20 g of distilled water. The washed reaction solution had a weight of 15.6 g. The washed reaction solution was poured into 100 g of n-heptane, to deposit orange fine particles. The fine particles were collected through filtration, dried at 60° C. for 12 hours, and thereby yielded 2.2 g of a polyol compound 2 for photoresists. The obtained polyol compound 2 for photoresists was subjected to a GPC measurement and found to have a weight-average molecular weight in terms of standard polystyrene of 800 and a molecular weight distribution of 1.26. Independently, the polyol compound 2 for photoresists was subjected to a ¹H-NMR measurement in dimethyl sulfoxide-d6 and found to show peaks from protons of phenolic hydroxyl groups at around 8 to 9 ppm, peaks from aromatic protons at around 6 to 7 ppm, and peaks from protons of adamantane ring at around 1 to 3 ppm.

### Example 3

In a 200-mL three-necked flask equipped with a Dimroth condenser, a thermometer, and a stirring bar were placed 2.18 g of 1,3,5-adamantanetriol, 7.82 g of hydroquinone, 13.51 g of p-toluenesulfonic acid, and 56.67 g of n-butyl acetate, followed by stirring thoroughly. Next, the flask was purged with nitrogen and submerged in an oil bath heated to 100° C. to start heating with stirring. After being kept heating under reflux for 2 hours, the flask was cooled.

The cooled reaction solution was transferred from the flask to a separatory funnel, washed with 80 g of distilled water, and further washed with five portions of 65 g of distilled water. The washed reaction solution had a weight of 55.4 g. The washed reaction solution was poured into 500 g of n-heptane, to deposit orange fine particles. The fine particles were collected through filtration, dried at 60° C. for 12 hours, and thereby yielded 5.2 g of a polyol compound 3 for photoresists. The obtained polyol compound 3 for photoresists was subjected to a GPC measurement and found to have a weight-average molecular weight in terms of standard polystyrene of 1310 and a molecular weight distribution of 2.08. Independently, the polyol compound 3 for photoresists was subjected to a ¹H-NMR measurement in dimethyl sulfoxide-d6 and found to show peaks from protons of phenolic hydroxyl groups at around 8 to 9 ppm, peaks from aromatic protons at around 6 to 7 ppm, and peaks from protons of adamantane ring at around 1 to 3 ppm.

### Example 4

In a 20-mL glass ampule were placed 0.2 g of the polyol compound 1 for photoresists obtained in Example 1, 0.003 g of p-toluenesulfonic acid, and 1.0 g of n-butyl acetate to give a homogeneous solution, and the ampule was purged with nitrogen and cooled with ice. Independently, 0.6 g of 5-vinyloxyadamantan-2-one and 1.0 g of n-butyl acetate were placed in a glass bottle to give a homogeneous solution, the glass bottle was then purged with nitrogen, the contents of which were added to the contents in the glass ampule, followed by stirring for 30 minutes with ice-cooling. The mixture was then further stirred at room temperature (25° C.) for 2 hours. Thereafter 30 g of methanol was poured thereinto to deposit solids, the solids were collected through filtration, dried at 30° C. for 12 hours, and thereby yielded 0.45 g of a compound 1-1 for photoresists.

The obtained compound 1-1 for photoresists was subjected to a GPC measurement and found to have a weight-average molecular weight in terms of standard polystyrene of 2050 and a molecular weight distribution of 1.85. Independently, the compound 1-1 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

### Example 5

The procedure of Example 4 was performed, except for using 2-(1-adamantyl)ethyl vinyl ether instead of 5-vinyloxyadamantan-2-one, to yield 0.40 g of a compound 1-2 for photoresists.

The obtained compound 1-2 for photoresists was subjected to a GPC measurement and found to have a weight-average molecular weight in terms of standard polystyrene of 1800 and a molecular weight distribution of 1.78. Independently, the compound 1-2 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

### Example 6

The procedure of Example 4 was performed, except for using 5-vinyloxy-3-oxatricyclo[4.2.1.0^{4.8}]nonan-2-one instead of 5-vinyloxyadamantan-2-one, to yield 0.48 g of a compound 1-3 for photoresists.

The obtained compound 1-3 for photoresists was subjected to a GPC measurement and found to have a weight-average molecular weight in terms of standard polystyrene of 2200 and a molecular weight distribution of 1.82. Independently, the compound 1-3 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

### Example 7

The procedure of Example 4 was performed, except for using 1-vinyloxy-4-oxatricyclo[4.3.1.1^{3.8}]undecan-5-one instead of 5-vinyloxyadamantan-2-one, to yield 0.48 g of a compound 1-4 for photoresists.

The obtained compound 1-4 for photoresists was subjected to a GPC measurement and found to have a weight-average molecular weight in terms of standard polystyrene of 2500 and a molecular weight distribution of 1.92. Independently, the compound 1-4 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

### Example 8

In a 200-mL three-necked flask equipped with a Dimroth condenser, a thermometer, and a stirring bar were placed 5.85 g of 1,3,5-adamantanetriol, 24.18 g of hydroquinone, 15.04 g of p-toluenesulfonic acid, and 170.02 g of n-butyl acetate, followed by stirring thoroughly. Next, the flask was purged with nitrogen and submerged in an oil bath heated to 140° C., to start heating with stirring. After being kept heating under reflux for one hour, the flask was cooled.

The cooled reaction solution was transferred from the flask to a separatory funnel, washed with 100 g of distilled water, and further washed with five portions of 100 g of distilled water. The washed reaction solution had a weight of 181.4 g. An aliquot (116.6 g) of n-heptane was poured into the washed reaction solution to cause an orange liquid to be separated as a different layer and to settle. The settled layer was removed using a separatory funnel, and the upper layer was further added to 207.9 g of heptane to cause a slightly yellow liquid to settle. This liquid was separated, dried at 45° C. for 8 hours, and thereby yielded 16.5 g of a polyol compound 4 for photoresists. The obtained polyol compound 4 for photoresists was subjected to a GPC measurement and found to have a weight-average molecular weight in terms of standard polystyrene of 1000 and a molecular weight distribution of 1.13.

### Example 9

In a 100-mL eggplant flask were placed 0.3 g of the polyol compound 4 for photoresists obtained in Example 8, 0.005 g of p-toluenesulfonic acid, and 12.0 g of n-butyl acetate to give a homogeneous solution, and the flask was purged with nitrogen. Independently, 0.5 g of cyclohexane vinyl ether and 6.0 g of n-butyl acetate were placed in a glass bottle to give a homogeneous solution, the glass bottle was purged with nitrogen, and the contents of which were added to the contents in the eggplant flask, followed by stirring at room temperature (25° C.) for one hour. The mixture was then poured into 100 g of a 3:1 (by weight) mixture of methanol and water to deposit solids, the deposited solids were collected through filtration, dried at 30° C. for 12 hours, and thereby yielded 0.38 g of a compound 4-1 for photoresists.

The obtained compound 4-1 for photoresists was subjected to a GPC measurement and found to have a weight-average molecular weight in terms of standard polystyrene of 1239 and a molecular weight distribution of 1.09. Independently, the compound 1-1 for photoresists was subjected to a ¹H-NMR measurement in dimethyl sulfoxide-d6 to find that the peaks from protons of phenolic hydroxyl groups, which had been observed at around 8 to 9 ppm, disappeared, demonstrating that phenolic hydroxyl groups were protected by protecting groups.

Evaluation Tests

The compounds 1-1, 1-2, 1-3, and 1-4 for photoresists obtained in Examples 4, 5, 6, 7, and 9 were evaluated respectively according to the following method.

Specifically, 100 parts by weight of a sample compound for photoresists, 5 parts by weight of triphenylsulfonium trifluoromethanesulfonate, and an appropriate amount of propylene glycol monomethyl ether acetate were mixed and thereby yielded a photoresist composition having a concentration of the compound for photoresists of 15 percent by weight.

The resulting photoresist composition was applied to a silicon wafer by spin coating so as to form a resist film 500 nm thick and prebaked on a hot plate at a temperature of 100° C. for 120 seconds. The resist film was then exposed to KrF excimer laser beams through a mask at an irradiance level of 30 mJ/cm², subjected to a PEB treatment at a temperature of 100° C. for 60 seconds, then developed with a 2.38% aqueous tetramethylammonium hydroxide solution for 60 seconds, and rinsed with pure water. As a result, all the samples gave 0.30 μm-wide line-and-space patterns.

### INDUSTRIAL APPLICABILITY

The polyol compounds for photoresists according to the present invention give compounds for photoresists by protecting phenolic hydroxyl group(s) thereof with a protecting group capable of leaving with an acid. Photoresist compositions containing any of the compounds can form resist patterns which show less LER, excel in resolution and etching resistance, and are fine and sharp.

1. A polyol compound for photoresists, comprising at least one aliphatic group and at least one aromatic group bound to each other alternately, the aromatic group having at least one aromatic ring and two or more hydroxyl groups bound to the aromatic ring.

2. The polyol compound for photoresists according to claim 1, as a product of an acid-catalyzed reaction between an aliphatic polyol and an aromatic polyol.

3. The polyol compound for photoresists according to claim 2, wherein the acid-catalyzed reaction is a Friedel-Crafts reaction.

4. The polyol compound for photoresists according to claim 2 or 3, wherein the aliphatic polyol is an alicyclic polyol.

5. The polyol compound for photoresists according to claim 2, wherein the aliphatic polyol is an adamantanepolyol having an adamantane ring and two or more hydroxyl groups bound at the tertiary positions of the adamantane ring.

6. The polyol compound for photoresists according to claim 2, wherein the aromatic polyol is hydroquinone.

7. The polyol compound for photoresists according to claim 2, wherein the aromatic polyol is a naphthalenepolyol.

8. The polyol compound for photoresists according to claim 1, wherein the polyol compound has a weight-average molecular weight of 500 to 5000.

9. A compound for photoresists, comprising one ore more phenolic hydroxyl groups in the polyol compound for photoresists of claim 1, the phenolic hydroxyl groups being protected by protecting groups capable of leaving with an acid in part or all of the phenolic hydroxyl groups.

10. The compound for photoresists according to claim 9, wherein an acetal structure is formed as a result of the protection of the phenolic hydroxyl group of the polyol compound for photoresists by the protecting group capable of leaving with an acid.

11. The compound for photoresists according to claim 10, wherein the acetal structure is formed through a reaction between the phenolic hydroxyl group and a vinyl ether compound.

12. A photoresist composition comprising at least the compound for photoresists according to claim 9.

13. A process for the formation of a resist pattern, the process comprising the steps of forming a resist film from the photoresist composition according to claim 12; pattern-wise exposing the resist film; and developing the pattern-wise-exposed resist film.

14. A process for the production of a polyol compound for photoresists, the process comprising the step of carrying out an acid-catalyzed reaction between an aliphatic polyol and an aromatic polyol to give a polyol compound containing at least one aliphatic group and at least one aromatic group bound to each other alternately, the aromatic group having at least one aromatic ring and two or more hydroxyl groups bound to the aromatic ring.

15. The process for the production of a polyol compound for photoresists, according to claim 14, further comprising the step of mixing a solution of the polyol compound for photoresists with a poor solvent with respect to a compound having one or more phenolic hydroxyl groups to deposit or separate as a different layer hydrophobic impurities to thereby remove the hydrophobic impurities, the polyol compound having been formed through the acid-catalyzed reaction between the aliphatic polyol and the aromatic polyol and containing at least one aliphatic group and at least one aromatic group bound to each other alternately, the aromatic group having at least one aromatic ring and two or more hydroxyl groups bound to the aromatic ring.

16. The process for the production of a polyol compound for photoresists, according to claim 15, further comprising the step of mixing the solution, from which the hydrophobic impurities have been removed, with a poor solvent with respect to a compound having one or more phenolic hydroxyl groups to thereby deposit or separate as a different layer the polyol compound for photoresists, the polyol compound containing at least one aliphatic group and at least one aromatic group bound to each other alternately, the aromatic group having at least one aromatic ring and two or more hydroxyl groups bound to the aromatic ring.

17. The process for the production of a polyol compound for photoresists, according to claim 15 or 16, wherein the poor solvent for use in the deposition or layer-separation of the hydrophobic impurities is one selected from the group consisting of a solvent mixture containing water and a water-miscible organic solvent; water; and a hydrocarbon.
